(19) United States
(12) Patent Application Publication
(10) Pub. No.: US 2025/0048501 A1
(43) Pub. Date: Feb. 6, 2025

(54) RESISTIVE HEATING DEVICE

(71) Applicant: Diamond Coatings Ltd, Halesowen, West Midlands (GB)

(72) Inventors: Jason Adrian EITE, Halesowen, West Midlands (GB); Andrew MCALLISTER, Halesowen, West Midlands (GB)

(21) Appl. No.: 18/715,335

(22) PCT Filed: Dec. 2, 2022
(86) PCT No.: PCT/GB2022/053078

§ 371 Date: May 31, 2024

(30) Foreign Application Priority Data
Dec. 3, 2021 (GB) 2117548.4

(51) Int. Cl. H05B 3/84; A42B 3/04; G01R 27/16; H05B 1/02; H05B 3/14

(52) U.S. Cl. CPC H05B 3/84; A42B 3/0406; G01R 27/16; H05B 1/02; H05B 3/141

(57) ABSTRACT

A device is described for driving resistive heating of one or more transparent oxide conductors supported by a transparent substrate. The device includes a driver circuit having an input for connection to a power supply and an output for connection to the one or more transparent oxide conductors. The driver circuit is configured to output a pulse-width modulated drive signal having a duty cycle. The device is configured to measure an impedance across the output. The device is also configured to control the driver circuit to output the drive signal in dependence upon the impedance. The device is configured to operate in one or more power modes. For each power mode, the device is configured to adjust the duty cycle of the pulse-width modulated drive signal to maintain the power dissipated by the drive signal at the pre-set power value corresponding to the active power mode.

### FIELD OF THE INVENTION

The present invention relates to a device for driving resistive heating of one or more transparent oxide conductors, and also to systems including the device and the use of the device.

### BACKGROUND

During cool or cold conditions, condensation (or ice) may build-up on the exterior or interior of transparent viewing panel, for example the windows and/or mirrors of a car (or other automobile having an enclosed passenger compartment). Two main approaches have been employed to prevent this. Firstly, automobiles typically include air vents that can be operated to direct warmed air at the windscreen, thereby heating the windscreen and preventing or reducing the build-up of condensation, frost and/or ice on the windscreen. Secondly, many automobile rear windscreens include small wires embedded in the glass. A current driven through these wires provides resistive (Joule) heating, warming the glass enough to prevent condensation. Although sometimes also used for front windscreens, resistive heating wires increase the cost and complexity of a viewing member, and this is often impractical in front windscreens, rear-view mirrors and the like, which more frequently require replacement due to impact damage (compared to rear windows which are rarely broken except in more serious collisions).

For viewing panels which are particularly sensitive to condensation build up, for example a visor of a protective helmet (such as for motorcycle or snowmobile riding) alternative solutions have been devised. For example, motorcycle visors have been known to include an insert that comprises a moisture absorbing layer. However, excessive moisture can cause this system to fail, resulting in visible drops or lines of water on the visor and a corresponding loss of visibility.

Another alternative for viewing panels such as visors has been application of a chemical compound just prior to use, which modifies the surface energy of the viewing panel to prevent condensation. However, many such “anti-fog” compounds are found by users to provide unsatisfactory performance.

### SUMMARY OF THE INVENTION

According to a first aspect of the invention, there is provided a device for driving resistive heating of one or more transparent oxide conductors supported by a transparent substrate. The device includes a driver circuit having an input for connection to a power supply and an output for connection to the one or more transparent oxide conductors. The device is configured to measure an impedance across the output. The device is also configured to control the driver circuit to output a drive signal in dependence upon the impedance.

The device may include a current sensor. The current sensor may include, or take the form of, a resistance having a known value. The current sensor may include, or take the form of, a Hall probe. The device may be configured to measure the impedance based on a voltage applied across the output and a current measured using the current sensor. The device may be configured to measure the impedance across the output using a resistance bridge circuit.

The one or more transparent oxide conductors may include, or take the form of, sheets of films of indium tin oxide (ITO). The one or more transparent oxide conductors may include, or take the form of, sheets or films of indium zinc oxide (IZO). Sheets or films of ITO and/or IZO may be patterned or un-patterned.

The device may be configured to operate in one or more power modes. For each power mode, the device may be configured to adjust one or more parameters of the drive signal in dependence upon the impedance, such that a power dissipated by the drive signal is equal to a pre-set power value corresponding to that power mode.

The one or more parameters of the drive signal may include a duty cycle of the drive signal. The one or more parameters of the drive signal may include an amplitude of the drive signal.

The one or more power modes may include a first power mode corresponding to a first pre-set power value, and a second power mode corresponding to a second pre-set power value higher than the first pre-set power value. The device may be configured to operate in three or more power modes, each corresponding to a different pre-set power value.

For a device intended for use with transparent conductors applied to a helmet visor, the first power mode may be 4 W and the second power mode may be 8 W.

The first power mode may correspond, when driving the transparent oxide conductor, to a power density of greater than or equal to 100 W·m⁻², greater than or equal to 200 W·m⁻², greater than or equal to 300 W·m⁻², or greater than or equal to 400 W·m⁻². The second power mode may correspond, when driving the transparent oxide conductor, to a power density of two or more times, three or more times, four or more times, or five or more times the first power mode.

The device may be configured, in response to being switched on, to operate in an initial power mode of the one or more power modes. The device may be configured, in response to a first time period has elapsed since being switched on, to switch to operating in a steady state power mode of the one or more power modes.

The initial power mode may be the second power mode. The steady state power mode may be the first power mode. The first time period may be between about 1 second and about 300 seconds, for example between about 10 seconds and about 60 second.

The device may include a power button configured to turn the device on and switch it off. The device may be configured to operate in a sleep or idle mode until woken up (i.e. switched on) in response receiving a wireless signal.

The device may be configured, in response to receiving a boost signal, to switch to operating in a boost power mode of the one or more power modes. The device may be configured, in response to a second time period has elapsed since receipt of the boost signal, to switch to operating in the steady state power mode of the one or more power modes.

The boost power mode may be the second power mode. The steady state power mode may be the first power mode. The second time period may be the same length as the first time period. The second time period may have a different same length to the first time period. The second time period may be between about 1 second and about 300 seconds, for example between about 10 seconds and about 60 seconds.

The device may also include a boost button configured to provide the boost signal in response to actuation.

The device may be configured to receive the boost signal via a wired or wireless link. The boost signal may be generated by actuating a button of a separate peripheral device connected to the device via the link. A wireless link may be a Bluetooth® connection, or a similar low power wireless protocol.

A boost button or a button of a separate peripheral may be configured for haptic feedback in dependence upon an operating power mode of the device. The boost button or the button of a separate peripheral may be coupled to an actuator configured to cause haptic vibrations, for example a piezoelectric transducer. The haptic vibration provided may depend on the operation mode. For example, a single pulse of vibration may indicate operation in the steady state power mode, and two pulses of vibration may indicate operation in the boost power mode. The haptic feedback may include as many different vibration patterns as there are power modes for the device.

The device may be configured to ignore a boost signal received within a third time period of an earlier boost signal. The third time period may preferably be longer than the second time period. The third time period may be between about 1 minute and 10 minutes.

The power supply may include a battery. The device may be configured to monitor a charge status of the battery. The device may be configured to ignore a received boost signal if a charge status of the battery is below a pre-set threshold. The battery may be external to the device. The battery may be integral to the device.

The device may be configured to measure the impedance in response to being switched on. The device may be configured to periodically measure the impedance. The device may be further configured to measure the impedance in response to receiving the boost signal.

The device may also include the power supply, and the power supply may include a battery. The battery may be rechargeable. The driver circuit input may also be used for recharging the battery using an external power source.

The driver circuit may be configured to output a pulse-width modulated drive signal having a duty cycle.

The device may be configured to adjust the duty cycle of the pulse-width modulated drive signal to maintain the power dissipated by the drive signal at the pre-set power value corresponding to the active power mode.

The device may be configured, in response to the measured impedance corresponds to an open circuit condition, to control the driver circuit to output no drive signal, and to output a first error condition.

The first error condition may be auditory, and may be output using a speaker included in the device. The first error condition may be visual, and may be output using one or more light sources included in the device (for example one or more light emitting diodes). The first error condition may be haptic, and may be output using a vibration generator included the device (for example a piezoelectric transducer). The first error condition may include a combination of two or more of auditory, visual and haptic outputs.

The device may be configured, in response to the measured impedance corresponds to an short-circuit condition, to control the driver circuit to output no drive signal, and to output a second error condition.

The second error condition may be output in any way described in relation to the first error condition. The second error condition may be the same as the first error condition. The second error condition may be different to the first error condition.

The device may be configured, in response to the measured impedance is outside a pre-set range, to control the driver circuit to output no drive signal, and to output a third error condition. The pre-set range may be between 10Ω and 50Ω.

The third error condition may be output in any way described in relation to the first and/or second error conditions. The third error condition may be the same as either or both of the first and second error conditions. The third error condition may be different to either or both of the first and second error conditions.

The device may also include a controller configured to measure the impedance across the output and to control the driver circuit to output the drive signal in dependence upon the impedance.

The controller may implement any or all of the functions and/or configurations of the device described herein. The controller may take the form of a microcontroller. The controller may include one or more digital electronic processors, volatile memory and non-volatile storage. The controller may include, or take the form of, an application specific integrated circuit (ASIC).

The signal output by the driver circuit may be configured to provide sufficient resistive heating to prevent condensation of water onto a face of the transparent substrate supporting the one or more transparent oxide conductors when a second, opposite face of the transparent substrate is exposed to a temperature of greater than or equal to −10 degrees Celsius, greater than or equal to −5 degrees Celsius, greater than or equal to −2 degrees Celsius, greater than or equal to 0 degrees Celsius, or greater than or equal to 5 degrees Celsius.

A system may include the device and one or more transparent oxide conductors connected to the driver circuit output (of the device).

At least one of the one or more transparent oxide conductors may include, or take the form of, indium tin oxide. All of the transparent oxide conductors may include, or take the form of, indium tin oxide. One, some, or all of the one or more transparent oxide conductors may include, or take the form of, indium zinc oxide.

The one or more transparent oxide conductors may be supported by a transparent substrate. The transparent substrate may include, or take the form of, glass. The transparent substrate may include, or take the form of, one or more transparent polymeric materials. The transparent substrate may take the form of a laminate, for example, safety glass.

The transparent substrate may be a helmet visor, for example for a motorbike. The transparent substrate may be the viewable portion of a pair of googles, glasses or the like. The transparent substrate may be a faceplate of a sealed environmental suit. The transparent substrate may be a window of a vehicle. The vehicle may be an automobile such as a car, truck, lorry, van, bus, coach and so forth. The vehicle may be a train. The system may be configured for connection of the driver circuit input to a power supply of a vehicle supporting, or intended to be used with, the system.

When the system includes the device configured with the boost power mode, the system may also include a peripheral device connected to the device via a link. The peripheral device may include a button configured to provide the boost signal in response to actuation. The link may be wired and/or wireless. A wireless link may be a Bluetooth® connection, or a similar low power wireless protocol.

According to a second aspect of the invention, there is provided a method including using the device to generate resistive heating in one or more transparent oxide conductors supported by a transparent substrate.

According to a third aspect of the invention, there is provided a method including using the system including the device.

### BRIEF DESCRIPTION OF THE DRAWINGS

Certain embodiments of the present invention will now be described, by way of example, with reference to the accompanying drawings in which:

FIG. 1 schematically illustrates a system for resistive heating;

FIG. 2 is a schematic block diagram of a device for driving resistive heating;

FIG. 3 is a process flow diagram for an exemplary method of controlling the device shown in FIG. 2;

FIG. 4 illustrates transitions between different power modes for resistive heating as a function of time; and

FIG. 5 schematically illustrates a pulse-width modulated signal.

### DETAILED DESCRIPTION

In the following description, like parts are denoted by like reference numerals.

The present inventors have found that it is possible to drive a transparent oxide conductor layer, for example formed of indium tin oxide (ITO) to generate heat and reduce, or event prevent, condensation. The present specification concerns a device for driving such transparent oxide conductor layers in a manner which may help to prolong the working lifetime of the transparent oxide conductor layer. In particular, the present specification concerns a device which may adjust to parameters of an output signal used to generate resistive heating in a transparent oxide conductor to control the total power output. Avoiding variations in dissipated power may avoid excessive power dissipation which may damage a transparent oxide conductor layer if its impedance (resistance) is reduced due to damage, wear-and-tear and/or variable environmental conditions. Transparent oxide conductors such as ITO may be significantly more affected by ambient conditions such as temperature and humidity, compared to conventional metallic conductors.

In addition to prolonging the lifetime of a transparent oxide conductor, further effects of the device shall become apparent from the description hereinafter, including but not limited to, improving lifetime when a device is battery powered and informing a user of possible faults/errors via a range of output options.

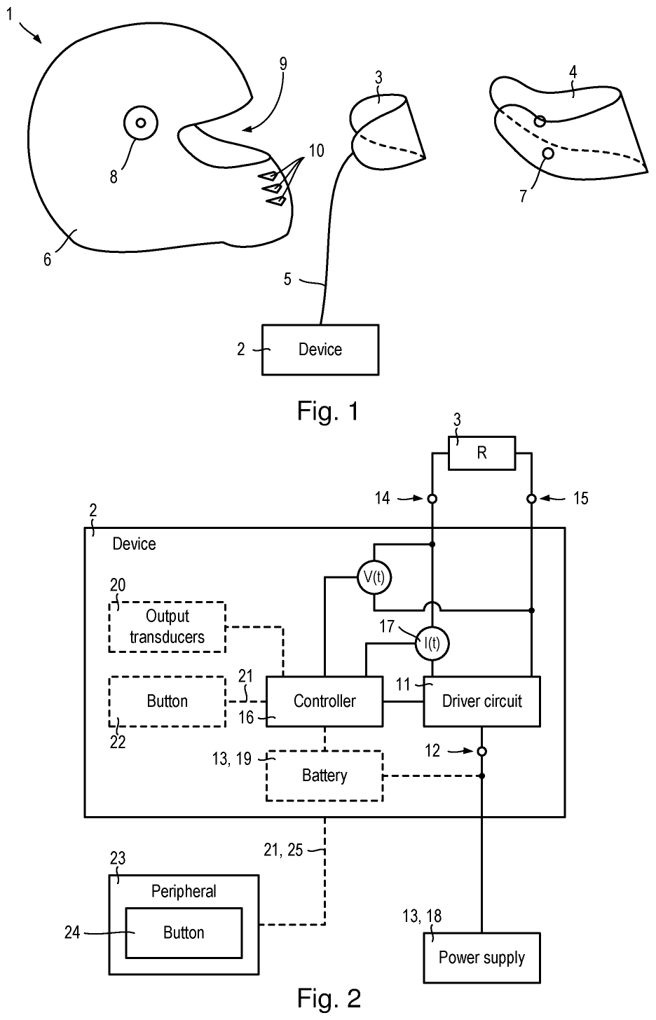

Referring to FIG. 1, a system 1 is shown.

The system includes a resistive heating device 2 (hereinafter simply “device”), a transparent oxide conductor 3 and a transparent substrate 4. The transparent oxide conductor 3 is connected to the device 2 by a wired connection 5 to enable passing a current through the transparent oxide conductor 3 for resistive heating.

Although a single transparent oxide conductor 3 is shown in FIG. 1, in general the device may drive any number of transparent oxide conductors 3, in any combination or series and/or parallel connections.

The exemplary system shown in FIG. 1 is for heating the interior of a transparent substrate 4 which is a visor for a motorbike helmet 6. The transparent substrate 4 in the form of the visor includes a first structure 7 which cooperates with a second structure 8 on the helmet 6 to enable the transparent substrate 4 to be mounted to the helmet 6 to cover an aperture 9 in the helmet 6. The first and second structures 7, 8 allow the transparent substrate 4 to be rotated to expose or cover the aperture 9. At high speeds and/or in cold weather/precipitation, a user will fold the visor down to cover the aperture 9 with the transparent substrate 4 to protect their eyes from debris, rain/snow and/or cold air.

Whilst helmets 6 typically include one or more vents 10 intended to prevent build of humidity and condensation on the interior of the transparent substrate/visor 4, in cold conditions the vents 10 may be insufficient to prevent condensation. However, by including the transparent oxide conductor 3 and heating it using the device 2, condensation may be reduced or even prevented.

The transparent oxide conductor(s) 3 may be formed of any suitable material, including but not limited to indium tin oxide (ITO), indium zinc oxide (IZO) and so forth. The transparent oxide conductor(s) 3 may be directly formed or deposited on the transparent substrate 4. Alternatively, the transparent oxide conductor(s) 3 may be formed or deposited on a carrier film (not shown), for example a thin flexible polymer film, which may then be bonded to an interior face of the transparent substrate 4 using an adhesive layer (not shown). The latter option may be useful for retro-fitting existing transparent substrates 4.

The transparent substrate 4 may be formed of any suitable materials, including but not limited to glass or transparent polymers such as polycarbonate. For helmets and transparent substrates 3 used as, for example, vehicle windows/windscreens, the transparent substrate 4 may often take the form of a laminate including two or more layers, mixing glass and polymer layers, for example safety glass.

Although the example shown in FIG. 1 concerns a transparent substrate 4 in the form of a visor for a helmet 6 for use when operating e.g. a motorbike, quadbike, snowmobile or the like, the system 1 may be readily adapted to any system or vehicle which may benefit from reducing or preventing condensation. For example, the transparent substrate 4 could be a viewable portion of a pair of googles, glasses, a faceplate of a sealed environmental suit and so forth. In other implementations, the transparent substrate 4 may be a window or windscreen of a vehicle such as, for example, a car, truck, lorry, van, bus, coach, train and so forth.

Referring also to FIG. 2, a block diagram of the device 2 is shown.

The device 2 include a driver circuit 11 having an input 12 for connection to a power supply 13 and an output 14, 14 for connection to the one or more transparent oxide conductors 3. The one or more transparent oxide conductors 3 are connected between terminals 14, 15 forming the output. The device 2 is configured to measure an impedance R across the output 14, 15, and to control the driver circuit 11 to output a drive signal V(t) in dependence upon the impedance R. A current I(t) flows in response to the drive signal V(t), in dependence on the impedance R.

The device 2 will typically include a controller 16 configured to control and coordinate the driver circuit 11, as well as other functions described hereinafter. The controller 16 takes the form of a microcontroller, or analogous component including one or more digital electronic processors, volatile memory for computations, and non-volatile storage to store program code. In some examples the controller 16 may include (or be provided by) an application specific integrated circuit (ASIC).

The device 2 may use any suitable method to measure the impedance R connected across the output 14, 15, for example using a current sensor 17 to determine the response I to an applied voltage V, according to Ohm's law V=IR. Any suitable current sensor 17 may be used, for example a resistance having a known value or a Hall probe. If the output signal V(t) is an alternating current (AC) signal, an inductance sensor may provide the current sensor 17. A voltage V across the output 14, 15 may be measured, for example, using an analog-to-digital input of the controller 16. If greater accuracy is required in determining the impedance, the device 2 may include a resistance bridge circuit (not shown).

The device 2 may be configured to operate in one of a number N of power modes PM₁, . . . , PMₙ, . . . , PM_{N}, with N a positive integer N≥1. For each power mode PMₙ, the device 2 may control/adjust one or more parameters of the drive signal V(t) in dependence upon the impedance R, such that a power I²R of resistive (or Joule) heating dissipated in the one or more transparent oxide conductors 3 is equal to a pre-set power value Pₙ corresponding to that power mode PMₙ. The controlled/adjusted parameters of the drive signal V(t) may include a duty cycle, an amplitude and so forth. A specific example of a pulse width modulated (PWM) drive signal V(t) is explained hereinafter with reference to FIG. 5.

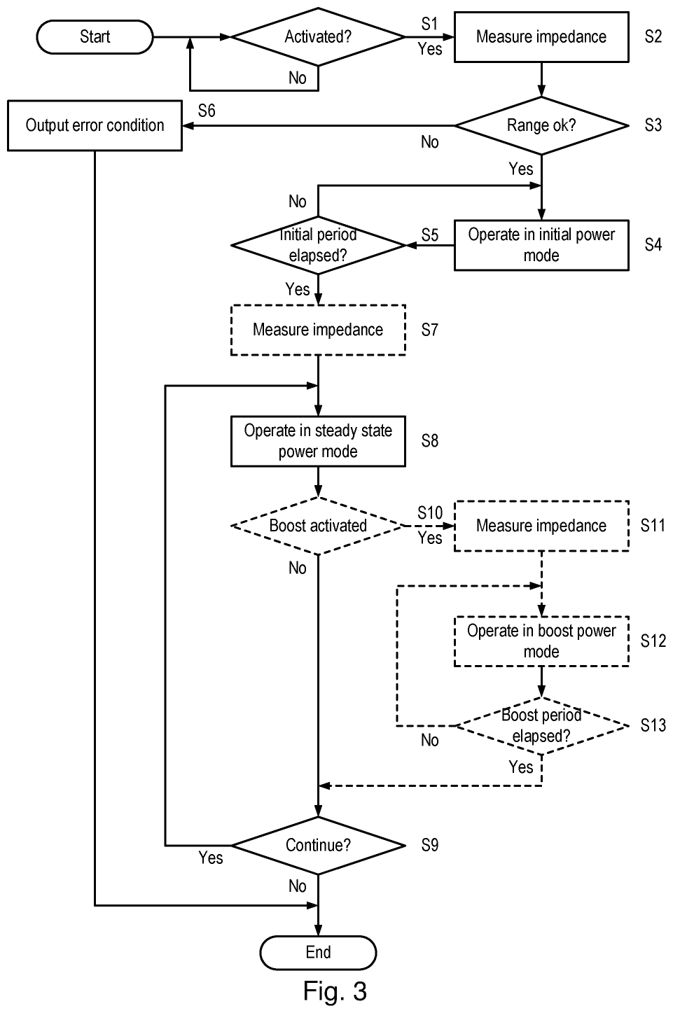

The N power modes may include (or consist of) a first power mode PM₁ corresponding to a first pre-set power value P₁, and a second power mode PM₂ corresponding to a second pre-set power value P₂ which higher than the first power value P₂<P₁. However, the number N of power modes PMₙ is not limited to two, and the device 2 may be configured to operate in each of three or more power modes PMₙ, each corresponding to a distinct power value Pₙ. As explained further in relation to FIG. 3, this may be allow a steady state power level to be temporarily boosted when particular conditions are met or in response to a user input.

As an example, for a device 2 intended for use a transparent substrate 4 in the form of a visor for a motorbike helmet 6, a first power mode PM₁ used for steady state heating may have P₁=4 W, whilst a second power mode PM₂ used for a temporary “boost” may have P₂=8 W.

The power supply 13 may take the form of an external power supply 18 and/or an internal battery 19. When included, the internal battery 19 may be rechargeable, and the device 2 may be connectable to the external power supply 18 both to power the device 2 and/or to recharge the internal battery 19. The external power supply 18 may be a main power supply of a vehicle such as a car, motorbike, train and so forth. In many cases, the external power supply 18 may be a battery, which may be integrated with a vehicle or may be a separate battery pack. It is not ruled out that the external power supply 18 could be a mains power outlet, for example if one or more transparent oxide conductors 3 were applied (e.g. using a self-adhesive carrier film not shown) to interiors of domestic windows which experience problematic condensation.

Although the output power required will vary with the specific application, the device 2 and the driver circuit 11 need to be able to drive sufficient resistive heating to prevent condensation of water onto a face of the transparent substrate 4 supporting the one or more transparent oxide conductors 3 when a second, opposite face of the transparent substrate 4 is exposed to a low temperature, for example −10 degrees Celsius or −5 degrees Celsius (different implementations may have different minimum operating temperatures).

Whilst the device 2 may in principle be operated in a single (N=1), constant power mode to maintain a constant power level P₁, additional and useful features may be provided by switching between two or more (N≥2) power modes PMₙ.

Referring also to FIG. 3, a process flow diagram of an exemplary control scheme for a device 1 is shown.

In response to being switched on (step S1|yes), the device 1 measures the impedance R of one or more transparent oxide conductors 3 which may be connected across the output 14, 15 (step S2). The value of impedance R measured is checked to ensure that it corresponds to an expected range (step S3).

The device 2 may include a power button (not shown). Alternatively, the device 2 may be configured to operate in a sleep or idle mode until woken up (i.e. switched on) in response receiving a wireless signal.

For example, the device 2 may be configured to determine that the impedance R is in range (step S3|yes) if the impedance R is greater than or equal to a minimum value Rₘᵢₙ and less than or equal to a maximum value Rₘₐₓ, i.e. Rₘᵢₙ≤R≤Rₘₐₓ. The range Rmin to Rmax may be determined based on calibrations performed in advance (e.g. in a factory or upon initial installation, for example performed using an ohmmeter).

However, if the impedance R is not within the expected range (step S3|No), i.e. R<Rₘᵢₙ or R>Rₘₐₓ, then an error condition is output (step S6). Multiple distinct error conditions may be determined, which may assist a user in identifying and/or rectifying a fault such as a poor connection.

For example, if the device 2 measures the impedance as corresponding to an open circuit condition (i.e. R is very high, out of range), then a first error condition may be output, and course the driver circuit 11 will not drive the output signal V(t). The first error condition may be output to a user using one or more output transducers 20 included in the device 1 (see FIG. 2). The output transducers 20 may include any combination of speakers, light sources such as light emitting diodes (LEDs) and/or vibration generators such as piezoelectric transducers, to output a first error condition. In this way, the first error condition may be one, or a combination, of an audible, visual and/or haptic alarm/alert.

In the case that the device 2 measures the impedance R as corresponding to a short-circuit condition (i.e. very low, almost zero impedance R), then a second error condition may be output using the output transducers 20 in any way described for the first error condition. Similarly, the driver circuit 11 should be controlled to prevent driving the output signal V(t). The second error condition may be the same as the first error condition, but is preferably different to assist a user in identifying and possibly rectifying any connection issues or more serious fault.

In the case that the device 2 measures the impedance R as being out of range, but not to such an extent as to correspond to a short-circuit or open-circuit, a third error condition may be output using the output transducers 20 in the same way described for the first and/or second error conditions. Again, the driver circuit 11 should be controlled to prevent driving the output signal V(t). The third error condition may be the same as the first and/or second error conditions, but is preferably different to either in order to provide useful differentiation.

By providing audible, visual and/or haptic alerts, it may be possible for a user to be informed of errors which may be correctable. For example, an audible beep/buzz may alert a user to an error, with the difference between open circuit, short-circuit or out-of-range impedance R indicated using different colours and/or patterns of LEDs (or different patterns of flashing/strobing LEDs). The user may then check a connection between the device 2 and the one or more transparent oxide conductors to ensure connectors have been (fully) inserted. Even if the error is not one the use can resolve, it is better to know in advance of departing. For example, in the case of a motorbike visor, if the device 2 is not functioning correctly and the user is unaware, they may have already reached a high speed road where it is dangerous to stop before they realise that condensation is building up.

Provided that the impedance R is in range (step S3|yes), the device 2 may start operating in an initial power mode PMᵢₙᵢ corresponding to an initial power value Pᵢₙᵢ (step S4). The device may operate in the initial power mode PMᵢₙᵢ until an initial (or first) period Δtᵢₙᵢ has elapsed (step S5). During the initial power mode PMᵢₙᵢ, the output signal V(t) is controlled so that the resistive heating I²R in the impedance is equal to the power value Pᵢₙᵢ. The appropriate initial time period Δtᵢₙᵢ may depend on a variety of factors including, for example, the power density (i.e. the power value Pᵢₙᵢ divided by the area of the transparent conductive oxide 3 being driven), but may generally be between about 1 second and 300 seconds.

Once the initial (first) period Δtᵢₙᵢ has elapsed (step S5|yes), the device 2 switches to a second, steady state power mode PMₛₛ corresponding to a steady state power value Pₛₛ (step S8). Optionally, the measurement of impedance R may be repeated (step S7) upon transitioning to the steady state power mode PMₛₛ and/or periodically during operation of the steady state power mode PMₛₛ. This may be helpful in compensating for any change in the resistance of the one or more transparent oxide conductors once they have been warmed during the initial period Δtᵢₙᵢ.

Whilst the device 2 remains active (step S9|yes), the steady state power mode PMₛₛ is maintained.

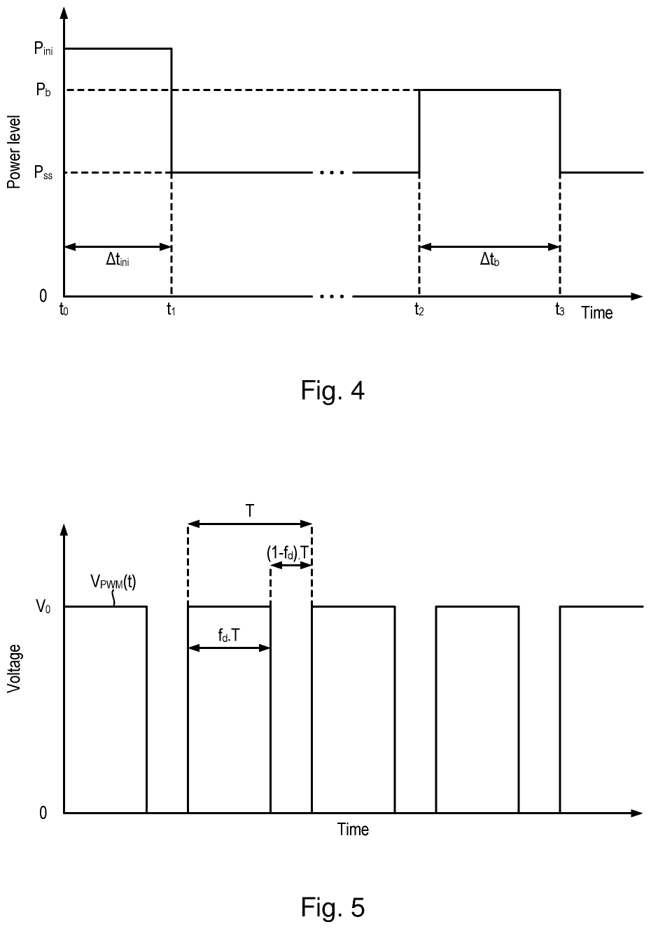

Referring also to FIG. 4, the initial period Δtᵢₙᵢ is illustrated.

After switching on and confirming that the impedance R is within the allowed range (steps S1 through S3), the device 2 starts operating in the initial power mode PMᵢₙᵢ at time to (step S4). The device 2 continues, with the output signal V(t) controlled to deliver power Pᵢₙᵢ to the one or more transparent conductive oxides 3 until the initial period Δtᵢₙᵢ has elapsed at time t₁=tₒ+Δtᵢₙᵢ (step S5|yes). The device 2 transitions to the steady state power mode PMₛₛ, with the output signal V(t) controlled to deliver power Pₛₛ, from time t₁ onwards.

Referring again to FIG. 3, an optional boost power mode PM_{b} may be triggered during the steady state power mode PMₛₛ.

In response to receiving a boost signal 21 (step S10|yes), the device 2 may switch to operating in a boost power mode PM_{b} (step S12) until a boost (or second) time period Δt_{b} has elapsed (step S13|yes). The boost power mode PM_{b} corresponds to a boost power value P_{b} which is greater than that steady state power value Pₛₛ. The boost power value P_{b} may be equal to the initial power value Pᵢₙᵢ, but does not need to be. Once the boost (or second) time period Δt_{b} has elapsed (step S13|yes), the device 2 returns to operation in the steady state power mode PMₛₛ (steps S8 and S9). The boost (or second) time period Δt_{b} may be the same duration as the initial (or first) time period Δtᵢₙᵢ, but does not need to be.

Optionally, the measurement of impedance R may be repeated (step S11) upon transitioning to the boost power mode PM_{b} and/or periodically during operation of the boost power mode PM_{b}. This may be helpful in compensating for any change in the resistance of the one or more transparent oxide conductors due to environmental factors such as temperature and/or humidity.

Referring again to FIG. 4, if the boost signal 21 is received at time t₂ (step S10|yes), the device 2 transitions to operating in the boost power mode PM_{b} (step S12). The device 2 continues, with the output signal V(t) controlled to deliver the boost power value P_{b} to the one or more transparent conductive oxides 3 until the boost period Δt_{b} has elapsed at time t₃=t₂+Δt_{b} (step S13|yes). The device 2 then transitions back to the steady state power mode PMₛₛ, with the output signal V(t) controlled to deliver power Pₛₛ.

Referring again to FIG. 2, the device 2 may include a button 21 configured to provide the boost signal 21 in response to actuation. The button 21 may also be used to switch the device on and off. For example, pressing and holding the button 21 down may cause the device 2 to switch between on and off states, whereas pressing the button 21 and immediately releasing the button 21 may trigger the boost signal 21 when the device 2 is already active.

Additionally or alternatively, the device 2 may be configured to receive the boost signal 21 from a separate peripheral device 23. The peripheral device 23 may be a wearable device such as a ring, a bracelet and so forth, or may be a small device attached to the controls of a vehicle. For example, when the device 2 is used to heat one or more transparent conductive oxide conductors 3 supported on a transparent substrate 4 provided a visor of a motorbike helmet, the peripheral device 23 may be attached to the handlebars of a motorbike. The peripheral device 23 includes a button 24, and generates the boost signal 21 in response to actuation of the button 24. In the motorbike example, this may be done without the user needing to remove their hands from the handlebars, for example using a thumb. The button 24 of the peripheral 23 may also be used to switch the device 2 on or off in the same way as the integral button 22.

The peripheral device 23 is connected to the device 2 by a link 25. The link 25 may be wired, but preferably is wireless to avoid the need for potentially entangling cables. The link may be a Bluetooth® connection, or a similar low-power wireless protocol.

Either or both of the buttons 22, 24 may be configured to provide haptic feedback indicating the presently active power mode PMₙ of the device 2. For example, either or both buttons 22, 24 may be coupled to an actuator to cause haptic vibrations (such as a piezoelectric transducer). The haptic vibration provided may depend on the active power mode PMₙ, and may be triggered by a user pressing the respective button 22, 24. For example, a single pulse of vibration may indicate operation in the steady state power mode PMₛₛ, and two pulses of vibration may indicate operation in the boost power mode PM_{b}. Double action buttons may be used, such that a light press triggers the haptic feedback, and a further, heavier press triggers the boost signal 21 (or if held, switches on/off). In this way, a user can readily determine which power mode PMₙ is currently active by touch.

In order to conserve power when the input 12 is supplied by an internal battery 19, and also to slow degradation of transparent oxide conductors 3 which may be associated with high power levels, the device 2 may optionally be configured to ignore a boost signal 21 received with a cooling off (or third) time period Δt_{cool} of the last boost signal 21 resulting in a transition to the boost power mode PM_{b}. The cooling off period Δt_{cool} is at least as long as the boost period Δt_{b}, and more typically may be several times the duration of the boost period Δt_{b}.

When the power supply 13 takes the form of a battery 19, the device 2 may be configured to monitor a charge state of the battery 19. For example, the controller 16 may monitor the current sensor 17 and keep track of the total charge supplied since the battery was last charged. If the charge state of the battery has dropped below a threshold level, the device 2 may switch to a low-power mode in which the boost signal 21 will be ignored to preserve the remaining battery 19 charge for as long as possible.

### Controlling Power Dissipation Using Pulse-Width Modulated Signals

Whilst it is possible to modulate parameters such as amplitude of an output signal V(t) to adjust the power dissipation in the impedance R, a pulse width modulated output signal V_{PWM}(t) may be implemented using a small number of components and may minimise power dissipation outside of the transparent oxide conductors 3 (thereby extending operating time when a battery 19 is used as the power supply 13). For example, using a (generally) fixed voltage output source such as a battery 19, the voltage applied to the impedance R may be modulated using a potential divider, at the cost of power being dissipated in the driver circuit 12 instead of the transparent oxide conductor 3. By contrast, a pulse width modulated output signal V_{PWM}(t) may be implemented by simply connecting and disconnecting the output. For example, using the controller 16 to switch the gate of a transistor and complete/break a circuit through the transparent conductive oxides.

Referring also to FIG. 5, a pulse-width modulated output signal V_{PWM}(t) is shown.

The pulse-width modulated output signal V_{PWM}(t) has a period T, and a duty cycle f_{d}, so that that if the output voltage of the power supply 13 is Vₒ, then the pulse-width modulated output signal V_{PWM}(t) is equal to Vₒ for a duration f_{d}T each period, and zero otherwise. When applied to the impedance R, the power dissipated is:

$$P = \frac{{f}_{d} {TV}_{0} \frac{{V}_{0}}{R}}{T}$$

$$P = \frac{{f}_{d} {V}_{0}^{2}}{R}$$

So that for a desired fixed value of P, a known value of Vₒ and a measured impedance R, the duty cycle f_{d} may be calculated and used to control the driver circuit 12.

### Modifications

It will be appreciated that many modifications may be made to the embodiments hereinbefore described. Such modifications may involve equivalent and other features which are already known in the design, manufacture and use of devices for driving resistive heating, transparent oxide films and/or transparent substrates, and which may be used instead of or in addition to features already described herein. Features of one embodiment may be replaced or supplemented by features of another embodiment.

Although examples have been described in which one, two or three power modes PMₙ and corresponding power values Pₙ have been used (for example, PMᵢₙᵢ, PMₛₛ and PM_{b}), the number of power modes PMₙ, and the conditions for switching between them, are not limited to the examples presented herein.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicant hereby gives notice that new claims may be formulated to such features and/or combinations of such features during the prosecution of the present application or of any further application derived therefrom.

1. A device for driving resistive heating of one or more transparent oxide conductors supported by a transparent substrate, the device comprising:
a driver circuit having an input for connection to a power supply and an output for connection to the one or more transparent oxide conductors wherein the driver circuit is configured to output a pulse-width modulated drive signal having a duty cycle;
the device configured:
to measure an impedance across the output using a resistance bridge circuit or using a current sensor and a voltage applied across the output; and
to control the driver circuit to output the drive signal in dependence upon the impedance;
wherein the device is configured to operate in one or more power modes, wherein for each power mode, the device is configured to adjust the duty cycle of the pulse-width modulated drive signal to maintain the power dissipated by the drive signal at the pre-set power value corresponding to the active power mode.

2. A device according to claim 1, wherein the one or more power modes comprise a first power mode corresponding to a first pre-set power value, and a second power mode corresponding to a second pre-set power value higher than the first pre-set power value.

3. A device according to claim 1, wherein the device is configured:
in response to being switched on, to operate in an initial power mode of the one or more power modes;
in response to a first time period has elapsed since being switched on, to switch to operating in a steady state power mode of the one or more power modes.

4. A device according to claim 1, wherein the device is configured:
in response to receiving a boost signal, to switch to operating in a boost power mode of the one or more power modes;
in response to a second time period has elapsed since receipt of the boost signal, to switch to operating in the steady state power mode of the one or more power modes.

5. A device according to claim 4, wherein the device comprises a boost button configured to provide the boost signal in response to actuation.

6. (canceled)

7. A device according to claim 4, wherein the device is configured to ignore a boost signal received within a third time period of an earlier boost signal.

8. A device according to claim 4, wherein the power supply comprises a battery, and wherein the device is configured to monitor a charge status of the battery, the device being configured to ignore a received boost signal if a charge status of the battery is below a pre-set threshold.

9. A device according to claim 1, wherein the device is configured to measure the impedance in response to being switched on.

10. A device according to claim 1, wherein the device is configured to periodically measure the impedance.

11. (canceled)

12. A device according to claim 1, wherein the device is configured, in response to the measured impedance corresponds to an open circuit condition:
to control the driver circuit to output no drive signal; and
to output a first error condition.

13. A device according to claim 1, wherein the device is configured, in response to the measured impedance corresponds to an short-circuit condition:
to control the driver circuit to output no drive signal; and
to output a second error condition.

14. A device according to claim 1, wherein the device is configured, in response to the measured impedance is outside a pre-set range:
to control the driver circuit to output no drive signal; and
to output a third error condition.

15. A device according to claim 1, comprising a controller configured to measure the impedance across the output and to control the driver circuit to output the drive signal in dependence upon the impedance.

16. A device according to claim 1, wherein the signal output by the driver circuit is configured to provide sufficient resistive heating to prevent condensation of water onto a face of the transparent substrate supporting the one or more transparent oxide conductors when a second, opposite face of the transparent substrate is exposed to a temperature of greater than or equal to −10 degrees Celsius.

17. A system comprising:
the device according to claim 1; and
one or more transparent oxide conductors connected to the driver circuit output.

18. A system according to claim 17, wherein at least one of the one or more transparent oxide conductors comprises indium tin oxide.

19. A system according to claim 17, wherein the one or more transparent oxide conductors are supported by a transparent substrate.

20. A system according to claim 17, wherein the device comprises a boost button configured to provide the boost signal in response to actuation;
wherein the device is configured:
in response to receiving a boost signal, to switch to operating in a boost power mode of the one or more power modes;
in response to a second time period has elapsed since receipt of the boost signal, to switch to operating in the steady state power mode of the one or more power modes;
the system further comprising a peripheral device connected to the device via a link, the peripheral device comprising a button configured to provide the boost signal in response to actuation.

21. A system according to claim 17, wherein the transparent substrate takes the form of:
a helmet visor;
a viewable portion of a pair of googles;
a viewable portion of a pair of glasses; or
a faceplate of a sealed environmental suit.

22. A method comprising using a device to generate resistive heating in one or more transparent oxide conductors supported by a transparent substrate, the device comprising:
a driver circuit having an input for connection to a power supply and an output for connection to the one or more transparent oxide conductors wherein the driver circuit is configured to output a pulse-width modulated drive signal having a duty cycle;
the device configured:
to measure an impedance across the output using a resistance bridge circuit or using a current sensor and a voltage applied across the output; and
to control the driver circuit to output the drive signal in dependence upon the impedance;
wherein the device is configured to operate in one or more power modes, wherein for each power mode, the device is configured to adjust the duty cycle of the pulse-width modulated drive signal to maintain the power dissipated by the drive signal at the pre-set power value corresponding to the active power mode.

23. (canceled)
